(19) United States
(12) Patent Application Publication
(10) Pub. No.: US 2002/0174537 A1
(43) Pub. Date: Nov. 28, 2002

(54) Terminal insertion guide apparatus

(75) Inventors: Hisato Chujo, Yokkaichi-city (JP); Takaaki Nakaseko, Yokkaichi-city (JP)

Correspondence Address: GREENBLUM & BERNSTEIN, P.L.C., 1941 ROLAND CLARKE PLACE, RESTON, VA, 20191, US

(73) Assignee: SUMITOMO WIRING SYSTEMS, LTD., Yokkaichi-city (JP)

(21) Appl. No.: 10/141,003

(22) Filed: May 9, 2002

(30) Foreign Application Priority Data
May 11, 2001 (JP) 2001-141321

(51) Int. Cl. B23P 19/00; G01R 1/00; H01H 1/00

(52) U.S. Cl. 29/747; 29/748; 29/593

(57) ABSTRACT

A terminal insertion guide apparatus adapted to be used with a connector having a plurality of cavities, such that an electrical cable having a terminal can be connected to a selected cavity of the plurality of cavities, whereby the corresponding cavity is indicated to an operator. The apparatus includes a connector holder for holding the connector, an indicating plate for indicating when the selective cavity is positioned at a predetermined terminal insertion position, a detecting mechanism, a driving mechanism that moves the connector holder, and a controller that controls the driving mechanism. The connector holder is movable between the open position and the guide area, and is adapted to position each selected cavity of the connector at a position that is indicated by the indicating plate according to a predetermined sequence and in accordance with signals from the detecting mechanism.

### CROSS-REFERENCE TO RELATED APPLICATIONS

The present application claims priority under 35 U.S.C. §119 of Japanese Patent Application No. 2001-141321, filed on May 11, 2001, the disclosure of which is expressly incorporated by reference herein in its entirety.

### BACKGROUND OF THE INVENTION

1. Field of the Invention

This invention relates to a terminal insertion guide apparatus.

2. Description of Related Art

Generally, a wire harness is an electrical wiring system that constitutes a predetermined network and is assembled by connecting a plurality of electrical cables to a connector.

When producing a wire harness, it is necessary to form a circuit by inserting an electrical cable with a terminal into a cavity in a connector.

In a process of producing the wire harness, it is typically required and/or necessary to connect a given electrical cable with a terminal to one selected from a plurality of cavities in a connector.

However, it is not easy to connect a given electrical cable having a terminal attached thereto to a cavity selected from a plurality of cavities. It is possible to prevent error of insertion in a completely automated line by programming a sequence of insertion and a set-up of a polarity. However, in the case of manual insertion, there is the possibility of human error, even if a support mechanism for indicating a sequence of insertion is utilized.

### SUMMARY OF THE INVENTION

One object of the present invention is to provide a terminal insertion guide apparatus that can prevent human error and that has a high working property.

In order to achieve these objects, the present invention is directed to a terminal insertion guide apparatus that is adapted to be used with a connector having a plurality of cavities, such that when an electrical cable with a terminal attached thereto is connected to a corresponding cavity, the corresponding cavity is indicated to an operator.

The apparatus includes a connector holder for holding a connector such that the corresponding cavity is open so that the electrical cable is connected to the corresponding cavity. An indicating plate is provided for indicating a cavity selected from the plural cavities in the connector held in the connector holder at a predetermined terminal insertion position. A mechanism is provided for detecting the electrical cable with a terminal in the cavity indicated by the indicating plate. A driving mechanism is utilized for displacing the connector holder between an open position, wherein the connector holder is released from the indicating plate so that a connector can be attached to and/or inserted into and detached and/or removed from the connector holder, and a guide area. The indicating plate is adapted to indicate one cavity that is selected from a plural of cavities. A controller controls the driving mechanism so that the connector holder can be displaced between the open position and the guide area. The cavity which is to be indicated by the indicating plate is altered at and/or according to a predetermined sequence in accordance with signals from the detecting mechanism.

In the present invention, it is possible to displace the connector holder between the open position and the guide area by actuating the driving mechanism via the controlling mechanism. It is therefore possible to bring the connector into a position where an electrical cable having a terminal installed thereon can be inserted into the connector, when the required connector is attached to the connector holder. The indicating plate can indicate a selected cavity from a plural of cavities by driving and/or moving the connector in the guide area at a predetermined sequence in order to insert a corresponding electrical cable with a terminal into the selected cavity.

In the present invention, because an indicating plate indicates a selected cavity without resort to a displaying device, the indicating plate can indicate the selected cavity at the predetermined terminal insertion position and an operator can always carry out an insertion work at the same position.

According to one aspect of the invention, there is provided a terminal insertion guide apparatus adapted to be used with a connector having a plurality of cavities, such that an electrical cable having a terminal can be connected to a selected cavity of the plurality of cavities, whereby the corresponding cavity is indicated to an operator, wherein the apparatus include a connector holder for holding the connector, whereby the selected cavity is positioned to receive the terminal of the electrical cable, an indicating plate for indicating when the selective cavity is positioned at a predetermined terminal insertion position, a detecting mechanism for detecting when the electrical cable and/or the terminal is positioned in the selected cavity, a driving mechanism for moving the connector holder between an open position and a guide area, the open position being defined by a position whereby the connector holder is moved away from the indicating plate such that the connector can be positioned into or removed from the connector holder, and the guide area being defined by any number of positions whereby the indicating plate can indicate one or more selected cavities, and a mechanism for controlling the driving mechanism. The connector holder is movable between the open position and the guide area and is adapted to position each selected cavity of the connector at a position that is indicated by the indicating plate according to a predetermined sequence and in accordance with signals from said detecting mechanism.

The connector holder may be movably mounted to a horizontal frame and the horizontal frame may be movably mounted to a vertical frame. The vertical frame may be one of adjustably and securely mounted to a base, and the indicating plate may be one of adjustably and movably mounted to a base.

The apparatus may further include a switch which is engagable with the indicating plate, and may also include a biasing mechanism which biases the indicating plate away from engagement with the switch.

The connector holder may be slidably mounted to a mounting plate, and the indicating plate may be slidably mounted to a base. The mechanism for detecting when the electrical cable and/or the terminal is positioned in the selected cavity may be a photo-electric sensor, and the indicating plate may include at least one of an indicating edge, a chamfer, and a notch. Additionally, the connector holder may be movably mounted to a horizontal frame via a motor, and the horizontal frame may be movably mounted to a vertical frame via another motor. The controller that controls the driving mechanism may include a display, an audible device, a switch and a microprocessor.

The invention also contemplates a terminal insertion guide apparatus configured to allow an operator to install a cable having a terminal into a cavity of a connector that has a plurality of cavities. The apparatus may include a movable connector holder adapted to hold the connector, a movable indicating member adapted to indicate when a selected cavity is positioned at a predetermined terminal insertion position, a detecting mechanism for detecting when the terminal is positioned in the selected cavity, and a driving mechanism for moving the connector holder between an open position and a number of terminal installation positions. The open position is defined by a position whereby the connector holder is accessible to the connector thereby allowing the connector to be positioned into or removed from the connector holder, at least one of the terminal installation positions being defined by a position whereby the indicating member indicates a selected cavity, and a controller that controls the driving mechanism. The connector holder is movable between the open position and any number of terminal installation positions via the driving mechanism and according to at least one of a predetermined program sequence and signals from the detecting mechanism.

The connector holder may be movably mounted to a horizontal frame and the horizontal frame may be movably mounted to a vertical frame. The vertical frame may be one of adjustably and securely mounted to a base, and the indicating member may be slidable mounted to a base.

The apparatus may further include a switch which is engagable with the indicating member and a biasing mechanism which biases the indicating member away from engagement with the switch.

The detecting mechanism for detecting when the electrical cable and/or the terminal is positioned in the selected cavity be a photo-electric sensor, and the indicating member may include at least one of an indicating edge, a chamfer, and a notch.

Still further, the present invention provides for a terminal insertion guide apparatus configured to allow an operator to install a cable having a terminal into a cavity of a connector that has a plurality of cavities. The apparatus includes a movable connector holder configured to removably retain the connector, the connector holder being movable in a first plane, a movable indicating member configured to indicate when a selected cavity is positioned at a predetermined terminal insertion position. The indicating member is movable in a direction substantially perpendicular to the first plane. The apparatus further includes a detecting mechanism for detecting when the terminal is positioned in the selected cavity, a driving mechanism for moving the connector holder between an open position and a number of terminal installation positions, the open position being defined by a position whereby the connector holder can receive the connector thereby allowing the connector to be positioned into or removed from the connector holder, at least one of the terminal installation positions is defined by a position whereby the indicating member indicates a selected cavity, and a controller that controls the driving mechanism. The connector is movable between the open position and a position wherein the connector is disposed between the connector holder and the indicating member.

### BRIEF DESCRIPTION OF THE DRAWINGS

The present invention is further described in the detailed description which follows, in reference to the noted plurality of drawings by way of non-limiting examples of embodiments of the present invention, in which like reference numerals represent similar parts throughout the several views of the drawings, and wherein:

FIG. 1 shows a perspective view of an embodiment of a terminal insertion guide apparatus in accordance with the present invention;

FIG. 2 shows a perspective view of an embodiment of a terminal insertion guide apparatus in accordance with the present invention;

FIG. 3 shows a perspective view of an embodiment of a terminal insertion guide apparatus in accordance with the present invention;

FIG. 4 shows an exploded perspective view of a main part of a terminal insertion guide apparatus in an embodiment shown in FIG. 1;

FIGS. 5A and 5B show an operation of an indicating plate in an embodiment shown in FIG. 1, with FIG. 5A showing a top view of a portion of the apparatus and FIG. 5B showing a front view of a portion of the apparatus;

FIG. 6 shows a front elevation view of a control unit; and

FIG. 7 shows a block diagram of a control unit.

### DETAILED DESCRIPTION OF THE PRESENT INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

An embodiment in accordance with the present invention will be described below by referring to the drawings.

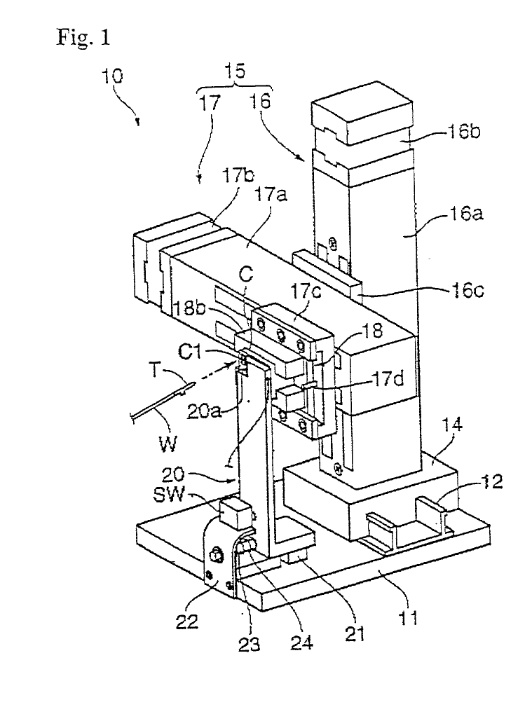

FIGS. 1 to 3 show a schematic construction of a terminal insertion guide apparatus 10 in an embodiment of the present invention.

In FIGS. 1 to 3, the terminal insertion guide apparatus 10 is a desktop type apparatus and includes a base plate 11 mounted on a table (not shown). An end of the base plate 11 in a longitudinal direction is directed toward an operator. Hereinafter, the term “front” means an operator's side (not shown).

A pair of rails 12 are secured on the base plate 11 to extend laterally on the base plate 11. A guide block 14 is slidably mounted on the rails 12 and fixed thereon by bolts (not shown) or other connection mechanisms, conventional or otherwise. A driving mechanism 15 is secured to the guide block 14. The driving mechanism 15 includes an elevating unit 16 that is directly fixed on the guide block 14 and a horizontal unit 17 that is movable up and down by the elevating unit 16. The units 16 and 17 include rectangular parallelepiped shaped (although other shapes may also be utilized) frames 16a and 17a. Motors 16b and 17b are mounted on the frames 16a and 17a. Additionally, ball screws (not shown), which are positioned longitudinally within the frames 16a and 17a, are utilized and are driven by the motors 16b and 17b. Mounting plates 16c and 17c are also employed and are coupled to nuts (not shown) engaged with the ball screws. The horizontal unit 17 is elevated through the mounting plate 16c by driving the motor 16b of the elevating unit 16. A connector holder 18 is detachably mounted on the mounting plate 17c and is driven laterally by driving the motor 17b of the horizontal unit 17.

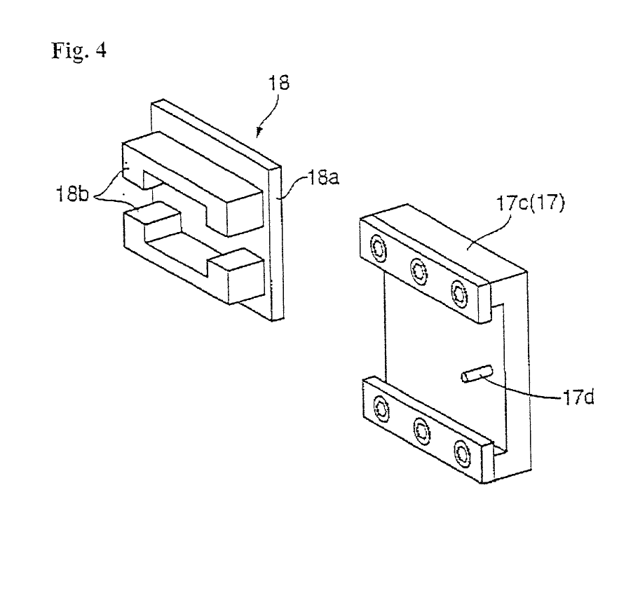

FIG. 4 illustrates an exploded perspective view of a main part of the terminal insertion guide apparatus 10 shown in FIG. 1.

As shown in FIG. 4, the mounting plate 17c of the horizontal unit 17 is a channel-like member that is made or otherwise assembled from any suitable material, such as metal plates. The connector holder 18 is detachably slid through an open side end onto the mounting plate 17c and a stopper or stop pin 17d is fixed upright on and/or projects from the other open side of the mounting plate 17c. This pin 17d is designed to stop and/or limit the movement of the connector holder 18.

The connector holder 18 includes a base plate 18a adapted to be held on the mounting plate 17c and a pair of holding blocks 18b fixed on the front side surface of the base plate 18a to detachably receive the connector C (see FIG. 1) in compliance with a contour of the connector C.

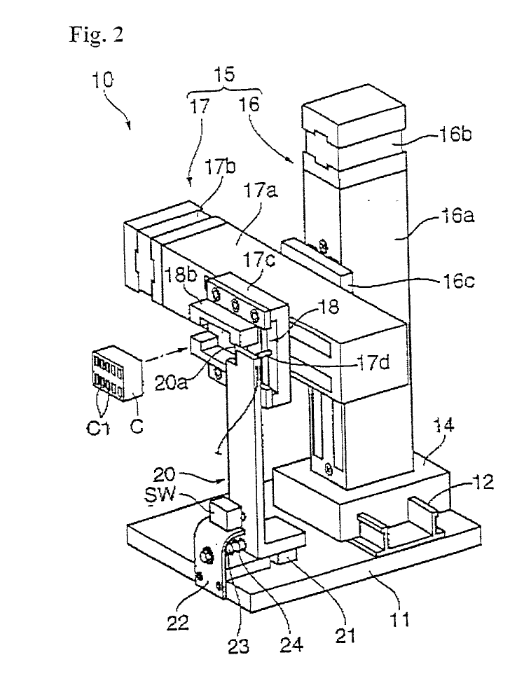

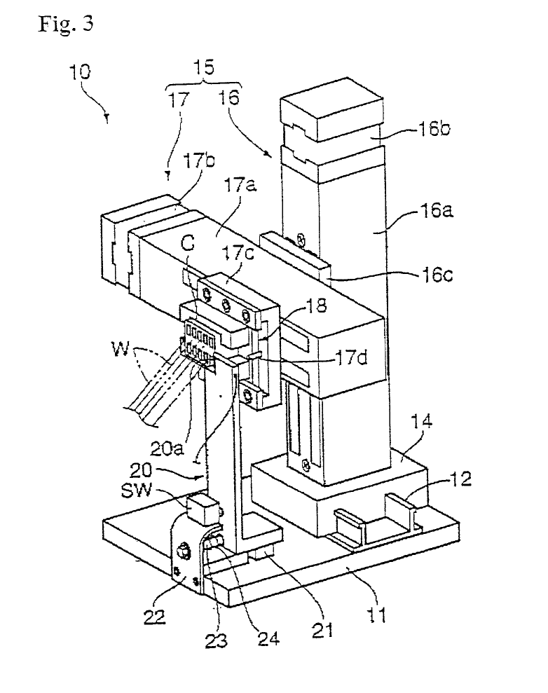

As shown in FIG. 1, the connector holder 18 can hold the connector C with the cavities C1 being open at the terminal insertion side, when the mounting plate 17c receives the connector holder 18 and the connector holder 18 receives the connector C. Once placed into the connector holder 18, the connector C can be moved between the open position (see FIG. 1) and the guide area (see FIGS. 2 and 3), as will be more fully described below. This movement is facilitated by coupling the connector holder 18 to the driving mechanism 15.

The indicating plate 20 is an L-shaped metal member. An upper portion of the plate 20 is designed to indicate to an operator the selected cavity C1 in the connector C. In the illustrated embodiment, the indicating plate 20 is attached and/or otherwise adjustably secured to the base plate 11 through a slider 21 that is secured to the bottom surface of the plate 20. The indicating plate 20 is displaced in the front and rear side directions by guiding the slider 21 in the front and rear side directions by rods (not shown). A cantilever-like stay 22 is secured to the base plate 11 at the front side of the indicating plate 20. A rod 23 is fixed on the stay 22 and extends towards the plate 20. A compression coil spring 24 is mounted around the rod 23 between the indicating plate 20 and the stay 22 to bias the indicating plate 20 toward a front side surface of the connector C, when the connector C is installed or otherwise positioned in the connector holder 18.

A microswitch SW is arranged on a top part of the stay 22. This allows the microswitch SW to be connected and/or otherwise activated or engaged, when the indicating plate 20 is moved toward the stay 22. The microswitch SW serves and/or is used to detect a failure of insertion of a terminal T, as described hereinafter.

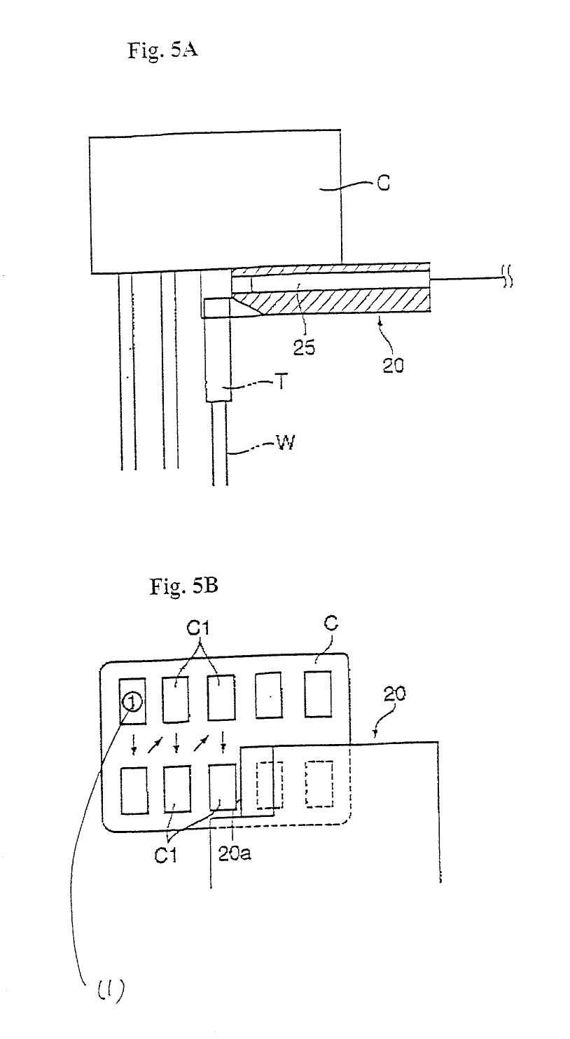

FIGS. 5A and 5B illustrate the operation of the indicating plate 20 according to the invention. Referring now to FIGS. 5A-B, it can be seen that the indicating plate 20 is provided in an upper portion with a notch 20a that is designed to guide a terminal T connected to an end of an electrical cable W into a selected cavity C1. The notch 20a indicates a terminal insertion position in which a terminal T of the electrical cable W is inserted into the selected cavity C1. The notch 20a is provided with a side edge having a chamfer for facilitating the insertion and/or guiding of the terminal T into the selective cavity C1.

As shown in FIG. 5A, the indicating plate 20 contains and/or otherwise includes a photoelectric sensor 25 which acts as a detecting mechanism. The sensor 25 is arranged adjacent to the side edge of the notch 20a and is designed to detect the electrical cable W with the terminal T attached thereto after it has been guided and inserted into the cavity C1 by way of the notch 20a.

The driving mechanism 15 and photoelectric sensor 25 mentioned above are both connected to a control unit 30, as will be described in more detail below.

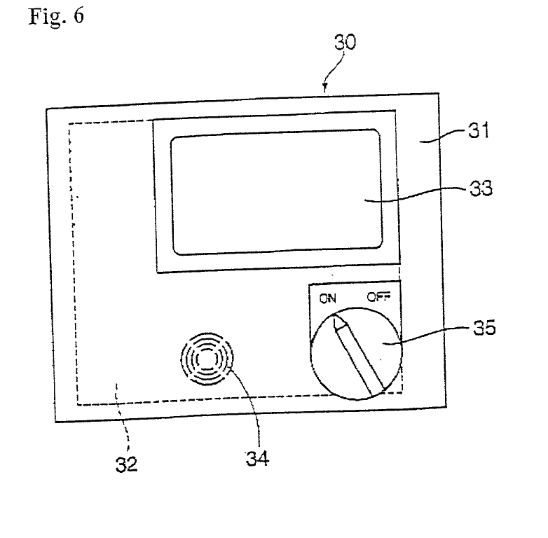

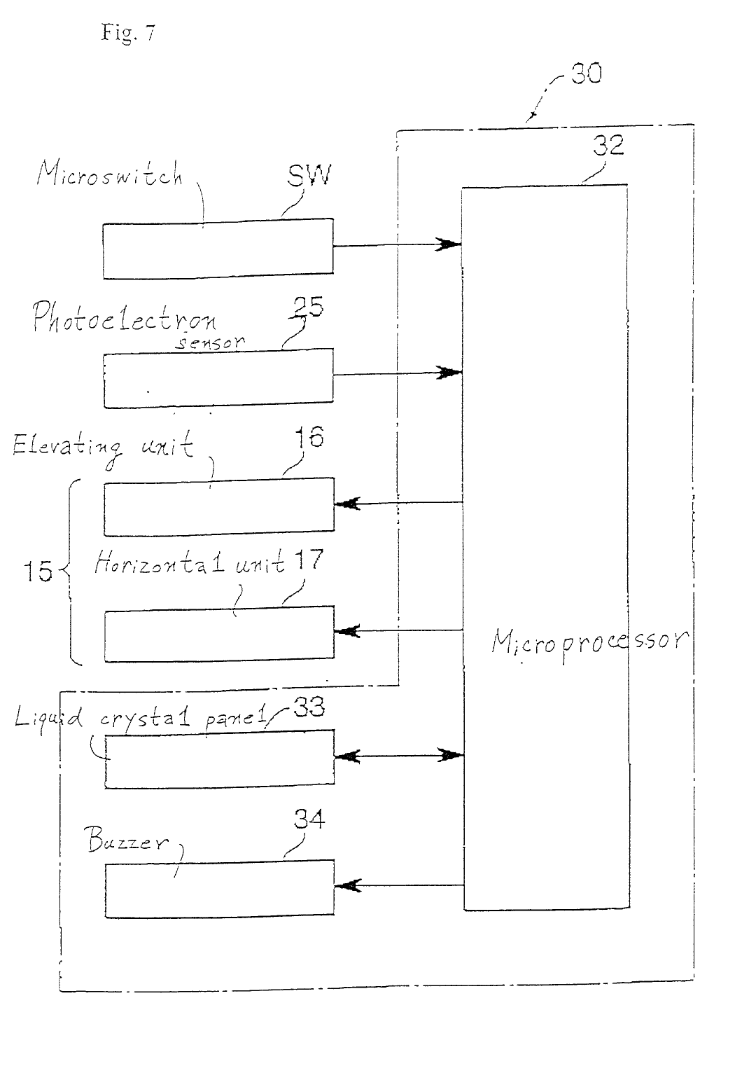

As can be seen in FIGS. 6 and 7, the control unit 30 includes a microprocessor 32 that is disposed in a box-like housing 31. The unit also includes a liquid crystal display or panel 33, an audible device such as, e.g., a buzzer 34, and a power switch 35. Each is arranged in the housing 31 and are all connected to the microprocessor 32. The microprocessor 32 is connected to the elevating unit 16 and to the horizontal unit 17 of the driving mechanism 15 via an interface (not shown). The microprocessor 32 is also connected to the microswitch SW and to the photoelectric sensor 25. The liquid crystal panel 33 is a display panel which serves to display and operate the apparatus.

The operation of the apparatus will now be described. In an initial stage, an operator selects and/or otherwise inputs a part-number in accordance with a menu displayed on the liquid crystal panel 33. Then the apparatus is ready for connecting one or more terminals T and electrical cables W to the required corresponding connector C.

After the operator sets a necessary controlling condition(s) such as the part-number of a corresponding connector C or the like information, the driving mechanism 15 is actuated to displace the connector holder 18 to the open position (see FIG. 1). The operator then attaches and/or positions the connector C into the connector holder 18. Thereafter, he operates the liquid crystal panel 33 to carry out a connection support operation. This causes the connection support operation to start. As a result, the microprocessor 32 actuates the units 16 and 17 of the driving mechanism 15 in accordance with predetermined program(s) and data. Then, the driving mechanism 15 moves successively (see FIG. 5B), in the directions shown by the arrows, the connector holder 18 to the terminal insertion position, e.g., (1) in FIG. 5B. Whereupon the notch 20a in the indicating plate 20 is used to indicate one selected from cavities C1. Note that in FIG. 5B, the notch 20a is shown to have already moved from the first cavity (1) in the upper row of cavities, to the third cavity from the left in the lower row of cavities.

With each position of the notch 20a adjacent a cavity C1, the photoelectric sensor 25 detects the electrical cable W having the terminal T, when the cable W is inserted into the selected cavity C1 at the terminal insertion position. The microprocessor 32 then waits for connection and/or actuation of the microswitch SW. At this stage, the operator draws or otherwise pulls on the cable W to check whether the terminal T has been fully inserted and/or is retained by the connector. This action detects whether a failure in the insertion of the terminal T in the cavity C1 has occurred after inserting the terminal T into the cavity C1. If there is no failure in insertion of the terminal T, the connector C will be caused to be drawn and/or moved away from the holding block 18b and towards the indicating plate 20. Such movement then causes the plate 20 to move towards the stay 22, thereby causing the connection and/or actuation of the microswitch SW. Based upon this connection and/or actuation, the microprocessor 32 determines that the terminal T is normally and/or properly inserted in the connector C and proceeds to the next operation. However, if there is a failure in insertion of the terminal T, e.g., such as when the terminal T is drawn out of the connector C, the operator is allowed to attempt another insertion of the terminal T into the connector C, whereupon this stage is repeated until actuation of the microswitch SW. Accordingly, at this stage, it is possible to positively prevent the failure in insertion of the terminal T.

When the microswitch SW is connected and/or actuated, the microprocessor 32 displays a message on the liquid crystal panel 33 and informs the next connection instruction(s) or correction procedure(s) to the operator. The microprocessor 32 then waits for operator to operate and/or provide inputs to the liquid crystal panel 33. When the operator operates the panel 33 to carry out the next connection instruction, the driving mechanism 15 is actuated again to move the next selected cavity C1 to the terminal insertion position, i.e., the next cavity which is to receive a terminal T is moved to a position adjacent the edge of the notch 20a. The above connection support operation will be repeated until all the required terminals are inserted into all of the required cavities C1.

The system can operate such that when the operator operates the panel 33 to carry out the correction works, the contents of control will be reset.

In the embodiment described above, the microprocessor 32 drives the driving mechanism 15 to move the connector holder 18 between the open position (see FIG. 1) and the guide area (see FIGS. 2-3). The corresponding connector C is attached to the connector holder 18 to ready it for insertion of the electrical cable W and the terminal T. The connector C is then moved to the guide area (see FIG. 2) to dispose and/or position the selected cavity C1 at the terminal insertion position indicated by the notch 20a in the indicating plate 20, thereby enabling the electrical cable W with the terminal T, to be inserted into the corresponding cavity. FIG. 3 illustrates an example of the connector C with a number of cables and terminals have been properly installed by the apparatus.

Rather than using a displaying device, the present invention instead utilizes an indicating plate 20 to indicate a selected cavity physically. As a result, it is possible to prevent and/or minimize human error in the insertion of one or more terminals T. Also, since the indicating plate 20 indicates a required cavity at the predetermined terminal insertion position, an operator can carry out an insertion operation at the same working position and enhance the working environment.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed is:

1. A terminal insertion guide apparatus configured to allow an operator to install a wire having a terminal into a selected cavity of a connector that has a plurality of cavities, said apparatus comprising:
a movable connector holder configured to hold the connector;
a movable indicating member configured to indicate when the selected cavity is positioned at a predetermined terminal insertion position;
a detecting mechanism that detects when the terminal is positioned in the selected cavity;
a driving mechanism that moves said connector holder between an open position and a number of terminal installation positions;
said open position being defined by a position whereby said connector holder is accessible to the connector thereby allowing the connector to be positioned into or removed from said connector holder;
at least one of the terminal installation positions being defined by a position whereby said indicating member indicates the selected cavity; and
a controller that controls the driving mechanism such that said connector holder is movable between the open position and any number of terminal installation positions via said driving mechanism and according to at least one of a predetermined program sequence and signals from said detecting mechanism.

2. The apparatus of claim 1, wherein said connector holder is movably mounted to a horizontal frame, and wherein said horizontal frame is movably mounted to a vertical frame

3. The apparatus of claim 2, wherein said vertical frame is one of adjustably and securely mounted to a base.

4. The apparatus of claim 1, wherein said indicating member is slidably mounted to a base.

5. The apparatus of claim 1, further comprising a switch which is engagable with said indicating member and a biasing mechanism which biases said indicating member away from engagement with said switch.

6. The apparatus of claim 1, wherein said detecting mechanism comprises a photo-electric sensor, and wherein said indicating member comprises at least one of an indicating edge, a chamfer, and a notch.

7. The apparatus of claim 1, wherein said indicating member is one of adjustably and movably mounted to a base.

8. The apparatus of claim 1, further comprising a switch engagable with said indicating member.

9. The apparatus of claim 8, further comprising a biasing mechanism which biases said indicating member away from engagement with said switch.

10. The apparatus of claim 1, wherein said connector holder is slidably mounted to a mounting plate.

11. The apparatus of claim 1, wherein said indicating member comprises a plate that is slidably mounted to a base.

12. The apparatus of claim 1, wherein said detecting mechanism comprises a photo-electric sensor.

13. The apparatus of claim 1, wherein said indicating member is a plate that comprises at least one of an indicating edge, a chamfer, and a notch.

14. The apparatus of claim 1, wherein said connector holder is movably mounted to a horizontal frame via a motor, and wherein said horizontal frame is movably mounted to a vertical frame via another motor.

15. The apparatus of claim 1, wherein said controller that controls said driving mechanism comprises a display, an audible device, a switch and a microprocessor.
